(19) United States
(12) Patent Application Publication
(10) Pub. No.: US 2013/0135549 A1
(43) Pub. Date: May 30, 2013

(54) THIN FILM TRANSISTOR ARRAY SUBSTRATE AND LIQUID CRYSTAL DISPLAY DEVICE AND METHOD FOR MANUFACTURING THE SAME

(71) Applicants: Songxian Wen, Shenzhen (CN); Jung-mao Tsai, Shenzhen (CN); Shiue-shih Liao, Shenzhen (CN); Yizhuang Zhuang, Shenzhen (CN); Mingfeng Deng, Shenzhen (CN); Xiaoxin Zhang, Shenzhen (CN)

(72) Inventors: Songxian Wen, Shenzhen (CN); Jung-mao Tsai, Shenzhen (CN); Shiue-shih Liao, Shenzhen (CN); Yizhuang Zhuang, Shenzhen (CN); Mingfeng Deng, Shenzhen (CN); Xiaoxin Zhang, Shenzhen (CN)

(21) Appl. No.: 13/380,051

(22) PCT Filed: Dec. 5, 2011
(86) PCT No.: PCT/CN2011/083441

§ 371 Date: Dec. 22, 2011

(30) Foreign Application Priority Data
Nov. 29, 2011 (CN) 201110387579.8

(51) Int. Cl. G02F 1/136; H01L 33/08

(52) U.S. Cl. 349/42; 438/30; 257/59; 257/E33.053

(57) ABSTRACT

The present invention discloses a thin film transistor (TFT) array substrate, a liquid crystal display (LCD) and a method for manufacturing the same. The method comprises: forming coating layers on a display region and a non-display region of a first substrate; forming a stacked layer on the non-display region; forming at least one channel on the stacked layer by exposure and developing; filling the channel with a sealant; and bonding the first substrate to a second substrate by using the sealant. The present invention can precisely control the shape of the sealant for preventing the leakage of the sealant and an uneven cell thickness.

### FIELD OF THE INVENTION

The present invention relates to a field of a liquid crystal display (LCD) manufacturing technology, and more particularly to a thin film transistor (TFT) array substrate, an LCD device and a method for manufacturing the same.

### BACKGROUND OF THE INVENTION

With the development of an LCD technology, the requirement to functionalities of the LCD is getting higher.

A TFT-LCD is composed of a TFT array substrate, a color filter (CF) substrate and a liquid crystal (LC) layer there between. In this case, the designed substrates of the TFT array substrate and the CF substrate are obtained by chemical or physical methods of film coating, exposure, developing and etching.

For preventing the LC molecules between the two substrates from contacting with the external environment, it is required to seal the TFT array substrate and the CF substrate by using a sealant under a vacuum environment. The main composition of the sealant is a resin which may be a thermosetting resin or a photo-curable resin.

In the conventional technology, when coating the sealant on the TFT array substrate or the CF substrate, basically, a pattern is first formed on a substrate, and then the sealant is coated according to a shape of the pattern. However, the above-mentioned coating manner easily results in uneven width and height of the coated sealant. This causes a leakage of the sealant and an uneven cell thickness after bonding the TFT array substrate or the CF substrate. Furthermore, in the above-mentioned coating manner, the sealant will directly contact with the LC molecules, resulting in a contamination of the LC molecules, deteriorating a display effect of the LCD.

### SUMMARY OF THE INVENTION

An object of the present invention is to provide a method for manufacturing an LCD device, so as to solve the technical problems that, in the conventional technology, a leakage of the sealant and an uneven cell thickness are likely to arise after bonding the TFT array substrate and the CF substrate due to the unevenness of the width and height of the sealant, and the sealant will directly contact with the LC molecules, resulting in a contamination of the LC molecules. deteriorating a display effect of the LCD.

For solving the above-mentioned problems, the present invention provides a method for manufacturing an LCD device, and the method comprises the following steps: providing a first substrate, wherein the first substrate has a display region and a non-display region, and the non-display region is positioned around the display region; forming coating layers on the display region and the non-display region, wherein the coating layers comprise a gate insulating layer, an amorphous silicon layer and an ohmic contact layer; patterning the coating layers on the display region and the non-display region, respectively, so as to form a switch array on the display region and form a stacked layer on the non-display region; forming at least one channel on the stacked layer by exposure and developing; filling the channel with a sealant, wherein the sealant is higher than a top side of the channel by a bonding distance; and bonding the first substrate to a second substrate by using the sealant.

In the method for manufacturing the LCD device of the present invention, the stacked layer has a support height, and a total height of the support height and the bonding distance is equal to an inside distance between the first substrate and the second substrate after bonding them.

In the method for manufacturing the LCD device of the present invention, the stacked layer comprises one or more layers of the gate insulating layer, the amorphous silicon layer and the ohmic contact layer.

In the method for manufacturing the LCD device of the present invention, when forming the channel on the stacked layer by exposure and developing, the channel and a pixel electrode on the display region are formed in the same mask process.

Another object of the present invention is to provide a method for manufacturing an LCD device, so as to solve the technical problems that, in the conventional technology, a leakage of the sealant and an uneven cell thickness are likely to arise after bonding the TFT array substrate and the CF substrate due to the unevenness of the width and height of the sealant, and the sealant will directly contact with the LC molecules, resulting in a contamination of the LC molecules, deteriorating a display effect of the LCD.

For solving the above-mentioned problems, the present invention provides a method for manufacturing an LCD device, and the method comprises the following steps: providing a first substrate, wherein the first substrate has a display region and a non-display region, and the non-display region is positioned around the display region; forming coating layers on the display region and the non-display region; patterning the coating layers on the display region and the non-display region, respectively, so as to form a switch array on the display region and form a stacked layer on the non-display region, wherein the stacked layer comprises at least one of the coating layers; forming at least one channel on the stacked layer by exposure and developing; filling the channel with a sealant; and bonding the first substrate to a second substrate by using the sealant.

In the method for manufacturing the LCD device of the present invention, the sealant is higher than a top side of the channel by a bonding distance, and the stacked layer has a support height, and a total height of the support height and the bonding distance is equal to an inside distance between the first substrate and the second substrate after bonding them.

In the method for manufacturing the LCD device of the present invention, the coating layers comprise a gate insulating layer, an amorphous silicon layer and an ohmic contact layer, and the stacked layer comprises at least one of the gate insulating layer, the amorphous silicon layer and the ohmic contact layer.

In the method for manufacturing the LCD device of the present invention, when forming the channel on the stacked layer by exposure and developing, the channel and a pixel electrode of a switch array are formed at the same time.

Still another object of the present invention is to provide an LCD device, so as to solve the technical problems that, in the conventional technology, a leakage of the sealant and an uneven cell thickness are likely to arise after bonding the TFT array substrate and the CF substrate due to the unevenness of the width and height of the sealant, and the sealant will directly contact with the LC molecules, resulting in a contamination of the LC molecules, deteriorating a display effect of the LCD.

For solving the above-mentioned problems, the present invention provides an LCD device, and the LCD device comprises: a first substrate comprising: a switch array disposed on a display region of the first substrate; a stacked layer formed on a non-display region of the first substrate, wherein the stacked layer comprises at least one coating layer; and at least one channel formed on the stacked layer; a sealant coated in the channel; and a second substrate bonded to the first substrate by using the sealant.

In the LCD device of the present invention, the sealant is higher than a top side of the channel by a bonding distance, and the stacked layer has a support height, and a total height of the support height and the bonding distance is equal to an inside distance between the first substrate and the second substrate after bonding them.

In the LCD device of the present invention, the stacked layer comprises at least one of a gate insulating layer, an amorphous silicon layer and an ohmic contact layer.

Still another object of the present invention is to provide a TFT array substrate, so as to solve the technical problems that, in the conventional technology, a leakage of the sealant and an uneven cell thickness are likely to arise after bonding the TFT array substrate and the CF substrate due to the unevenness of the width and height of the sealant, and the sealant will directly contact with the LC molecules, resulting in a contamination of the LC molecules, deteriorating a display effect of the LCD.

For solving the above-mentioned problems, the present invention provides a TFT array substrate, and the TFT array substrate comprises: a substrate; a switch array disposed on a display region of the substrate; a stacked layer comprising at least one coating layer and formed on a non-display region of the substrate; and at least one channel formed on the stacked layer configured to fill a sealant.

In the TFT array substrate of the present invention, the sealant is higher than a top side of the channel by a bonding distance, and the stacked layer has a support height, and a total height of the support height and the bonding distance is equal to an inside distance between a first substrate and a second substrate after bonding them.

In the TFT array substrate of the present invention, the stacked layer comprises at least one of a gate insulating layer, an amorphous silicon layer and an ohmic contact layer.

In comparison with the conventional technique, the stacked layer of the present invention is formed on the non-display region during the process for forming the first substrate (such as TFT array substrate), and the channel is formed on the stacked layer, and then the sealant is coated into the channel. Therefore, the shape of the sealant can be precisely controlled for preventing the leakage of the sealant. Furthermore, the channel is formed inside the coating layers on the first substrate, so as to allow the sealant on the first substrate to have a constant height, thereby preventing an uneven cell thickness. Moreover, the sealant is coated in the channel for efficiently isolating the contact of the sealant and the LC molecules, preventing the contamination of the LC molecules, and improving the display effect of the LCD device.

The structure and the technical means adopted by the present invention to achieve the above and other objects can be best understood by referring to the following detailed description of the preferred embodiments and the accompanying drawings.

### DESCRIPTION OF THE DRAWINGS

FIG. 1 is a flowchart showing a method for manufacturing a liquid crystal display device according to a preferred embodiment of the present invention;

FIG. 2 is a top view showing the TFT array substrate according to the preferred embodiment of the present invention; and

FIG. 3A to FIG. 3E are schematic flow diagrams showing a process for forming the channel according to the preferred embodiment of the present invention.

### DETAILED DESCRIPTION OF THE PREFERRED EMBODIMENTS

The following embodiments are referring to the accompanying drawings for exemplifying specific implementable embodiments of the present invention.

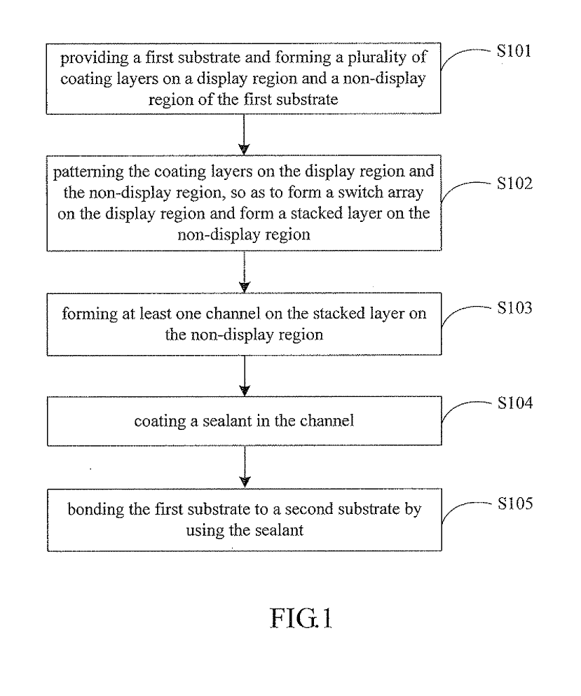

FIG. 1 is a flowchart showing a method for manufacturing a liquid crystal display device according to a preferred embodiment of the present invention.

In a step S101, a first substrate is provided, and a plurality of coating layers are formed on a display region and a non-display region of the first substrate.

For example, a first metal layer, a gate insulating layer, an amorphous silicon layer, an ohmic contact layer, a second metal layer, a transparent and electrically conductive layer and a passivation layer are deposited on the first substrate.

In practice, the first metal layer may be a TFT array substrate. Certainly, the first metal layer may be a substrate with a TFT array and color filters.

In a step S102, the coating layers on the display region and the non-display region are patterned, so as to form a switch array on the display region and form a stacked layer on the non-display region.

In practice, the coating layers which are coated in the step S101 are exposed, developed and etched, so as to form the switch (such as TFT) array on the display region of the first substrate.

In this embodiment, during the process of exposing, developing and etching the coating layers on the first substrate, the coating layers on the non-display region are reserved to form the stacked layer on the non-display region. For example, during the process of exposing and developing the gate insulating layer to form gate electrodes, the gate insulating layer on the non-display region is reserved to form the stacked layer.

In this embodiment, the stacked layer may comprise one or more layers of the gate insulating layer, the amorphous silicon layer, the ohmic contact layer and the passivation layer. Certainly, the stacked layer may comprise other coating layers, which are not enumerated here.

In a step S103, at least one channel is formed on the stacked layer on the non-display region.

In practice, when patterning the coating layers on the display region of the first substrate to form the switch array on the display region, the channel is formed on the stacked layer on the non-display region.

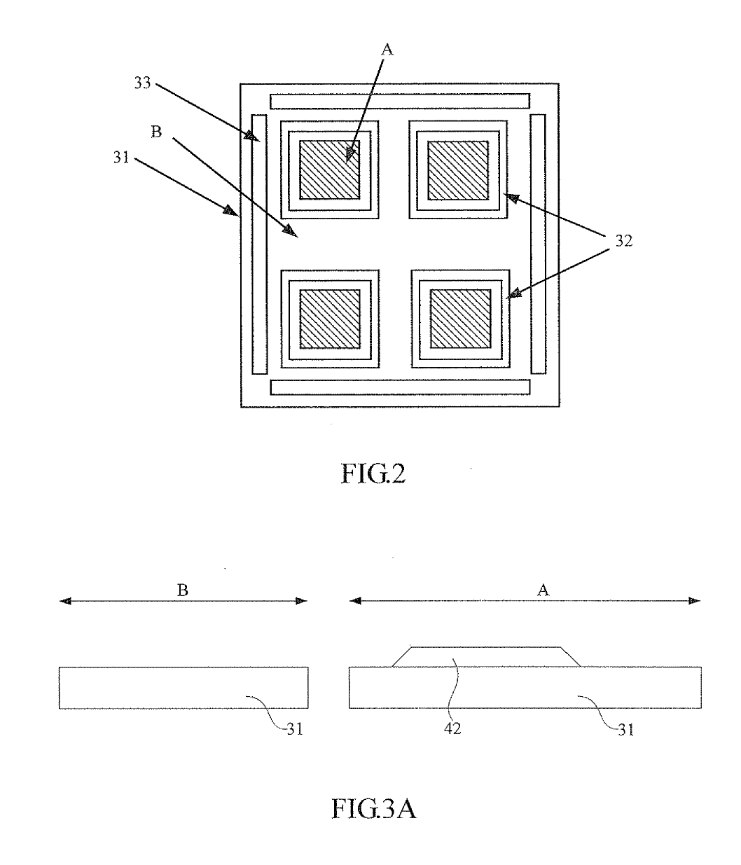

Referring to FIG. 2, a top view showing the TFT array substrate according to the preferred embodiment of the present invention is illustrated. In FIG. 2, the first substrate 31 comprises the display region A and the non-display region B, and the main channels 32 and sub-channels 33 are formed on the stacked layer (not shown) on the non-display region B. The main channels 32 are configured to receive main sealants, and the sub-channels 33 are configured to receive sub-sealants.

In a step S104, the sealant is coated in the channel.

In practice, a width of the channel is identical to a width of the uncured sealant, and a depth of the channel is substantially less than a height of the uncured sealant. More specifically, after filling a fluid of the sealant into the channel, the uncured sealant is higher than the top side of the channel by a bonding distance. The bonding distance of the sealant with respect to the op side of the channel is used to allow the TFT array substrate to be bonded to a CF substrate. For example, the bonding distance is 0.2 mm.

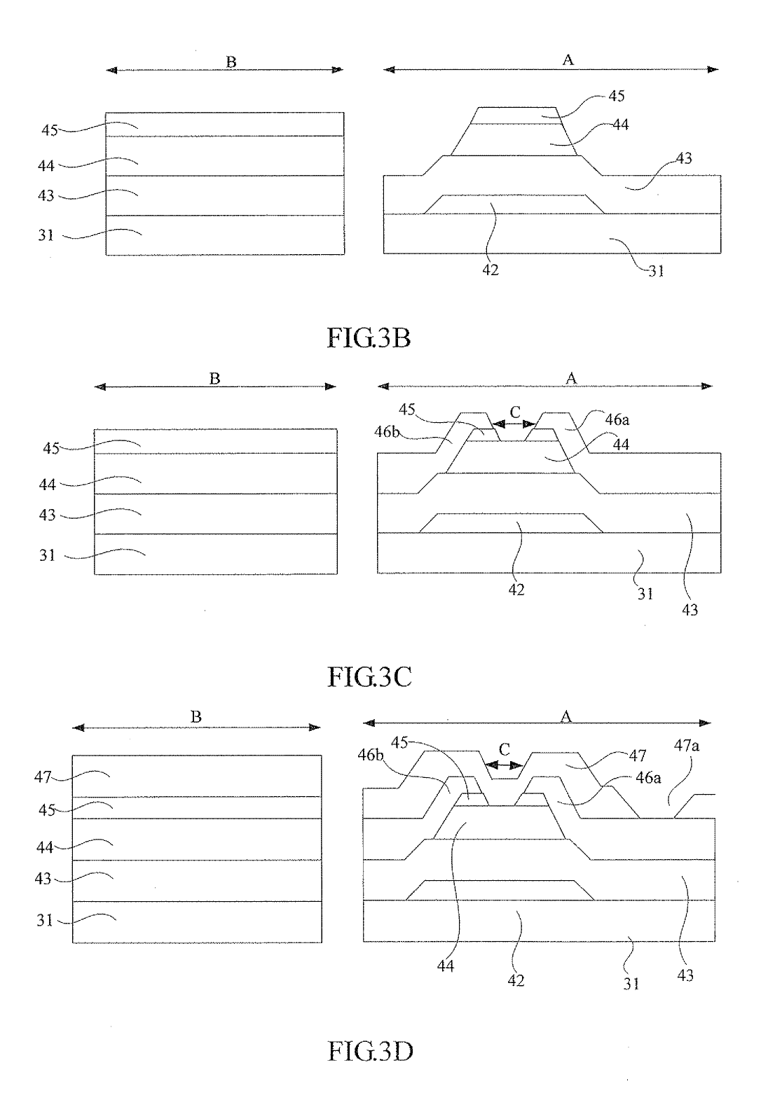

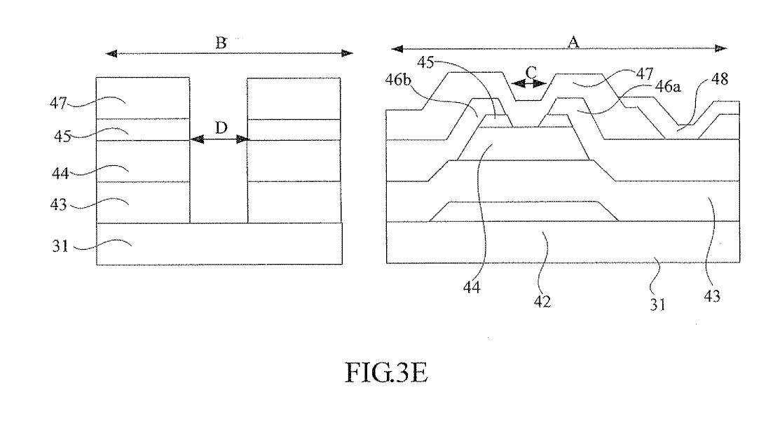

In this case, as shown in FIG. 3, the at least one coated sealant may comprise the main sealants in the main channels 32 and the sub-sealants in the sub-channels 33.

In practice, the stacked layer has a support height, and the total height of the support height and the bonding distance is equal to an inside distance between the first substrate 31 and the second substrate 32 after bonding them.

In a step S105, the first substrate and the second substrate are bonded as one-piece by using the sealant.

Referring to FIG. 3A through FIG. 3E, schematic flow diagrams showing a process for forming the channel according to the preferred embodiment of the present invention are illustrated. This embodiment is described with reference to an example of using mask processes to expose and develop for forming the switch (such as TFT) array and the channel (steps 102, 103) at the same time.

Referring to FIG. 3A again, gate electrodes 42 are formed on the display region A of the first substrate 31. The gate electrodes 42 are formed by means of a first mask process.

Referring to FIG. 3B again, the gate insulating layer 43, a semiconductor layer 44 and the ohmic contact layer 45 are formed on the first substrate 31 in sequence. The above-mentioned coating layers cover the display region A and the non-display region B of the first substrate 31 at the same time. Moreover, the semiconductor layer 44 and the ohmic contact layer 45 are patterned by exposing and developing of a second mask process, so as to form semiconductor islands on the gate insulating layer 43. At this time, the gate insulating layer 43, the semiconductor layer 44 and the ohmic contact layer 45 on the non-display region B are reserved, and not removed, so as to form the stacked layer (not shown).

Referring to HG. 3C again, drain electrodes 46a and source electrodes 46b are formed on the semiconductor islands by means of a third mask process, and channels C are formed between the drain electrodes 46a and the source electrodes 46b.

Referring to FIG. 3D again, the passivation layer 47 are formed on the channels C, the drain electrodes 46a and the source electrodes 46b by exposing and developing of a fourth mask process, wherein the passivation layer 47 has at least one contact hole 47a to expose a portion of the drain electrodes 46a. At this time, the passivation layer 47 on the non-display region B can be reserved, and not removed. In this case, the stacked layer comprises four coating layers of the gate insulating layer 43, the semiconductor layer 44, the ohmic contact layer 45 and the passivation layer 47 in sequence.

Referring to FIG. 3E again, a pixel electrode layer 48 is formed on the passivation layer 47 by exposing and developing of a fifth mask process. The pixel electrode layer 48 covers the contact hole 47a of the passivation layer 47, and thus the electrode layer 48 can be electrically connected to the drain electrodes 46a through the contact hole 47a of the passivation layer 47, so as to achieve the switch (such as TFT) array on the display region A of the first substrate 31. In the fifth mask process, the stacked layer (the gate insulating layer 43, the semiconductor layer 44, the ohmic contact layer 45 and the passivation layer 47) are patterned at the same time by exposing and developing of the fifth mask process, so as to form the channel D on the stacked layer. In this embodiment, the channel D is formed in the last mask process, thereby ensuring the depth of the channel D.

In this embodiment, the switch (TFT) array is achieved by means of five mask processes. However, in other embodiments, the switch array can be achieved by means of four or less mask processes, but not limited to the above description. Preferably, the channel D and the pixel electrode of the switch array are formed simultaneously in the same mask process (the last mask process), so as to simplify the process steps and ensure the depth of the channel D.

In the process of forming the first substrate of this embodiment, the coating layers on the non-display region of the first substrate are reserved to form the stacked layer, and the channel is formed on the stacked layer, and the sealant is coated into the channel. Therefore, the shape of the sealant can be precisely controlled for preventing a leakage of the sealant.

Furthermore, the channel is formed inside the coating layers on the first substrate, so as to allow the sealant on the first substrate have a constant height, thereby preventing an uneven thickness of the LC cell. Moreover, the sealant is coated in the channel for efficiently isolating the contact of the sealant and the LC molecules, preventing the contamination of the LC molecules, and improving the display effect of the LCD device.

The present invention further provides an LCD device.

In this case, the LCD device comprises the first substrate and the second substrate. The switch array is formed on the display region of the first substrate. The stacked layer is formed on the non-display region of the first substrate, and the stacked layer includes at least one coating layer, and the channel is formed on the stacked layer.

In this case, the channel is formed by exposing, developing and etching the stacked layer. The sealant is coated in the channel, and the first substrate and the second substrate are bonded by using the sealant in the channel.

In practice, the stacked layer may comprise one or more layers of the gate insulating layer, the amorphous silicon layer and the ohmic contact layer. Certainly, the stacked layer may comprise other coating layers, which are not enumerated here.

In practice, the channel is formed by using a mask to expose and develop the stacked layer. The mask has a pattern, and the shape of the pattern corresponds to the shape of the sealant, and the specific description can refer to FIG. 2 and the accompanying description thereof, which is not enumerated here.

In this case, the width of the channel is identical to the width of the sealant, and the sealant is higher than the top side of the channel by the bonding distance. Specifically, after filling the fluid of the sealant into the channel, the sealant is higher than the top side of the channel by the bonding distance. The bonding distance of the sealant with respect to the op side of the channel is used to allow the first substrate to be bonded to the second substrate. For example, the bonding distance is 0.2 mm.

In practice, the stacked layer has a support height, and the total height of the support height and the bonding distance is equal to an inside distance between the first substrate and the second substrate after bonding them.

The process of forming the channel in this embodiment is mentioned above, and will not be further described for simplification.

The present invention further provides a TFT array substrate.

The TFT array substrate comprises a substrate. The switch array is formed on the display region of the first substrate. The stacked layer is formed on the non-display region of the substrate, and the stacked layer includes the channel for coating the sealant.

In this case, the channel is formed by exposing, developing and etching the stacked layer. The stacked layer may comprise one or more layers of the gate insulating layer, the amorphous silicon layer and the ohmic contact layer.

In practice, the channel is formed by using a mask to expose and develop the stacked layer. The mask has a pattern, and the shape of the pattern corresponds to the shape of the sealant, and the specific description can refer to FIG. 2 and the accompanying description thereof, which is not enumerated here.

In this case, the width of the channel is identical to the width of the sealant, and the sealant is higher than the top side of the channel by the bonding distance. Specifically, after filling the fluid of the sealant into the channel, the sealant is higher than the top side of the channel by the bonding distance. The bonding distance of the sealant with respect to the op side of the channel is used to allow the first substrate to be bonded to the second substrate. For example, the bonding distance is 0.2 mm.

In practice, the stacked layer has a support height, and the total height of the support height and the bonding distance is equal to an inside distance between the first substrate and the second substrate after bonding them.

The process of forming the channel in this embodiment is mentioned above, and will not be further described for simplification.

In this embodiment, the stacked layer is formed on the non-display region during the process for forming the TFT array substrate. The stacked layer comprises at least one coating layer, and the channel is formed on the stacked layer, and the sealant is coated into the channel. Therefore, the shape of the sealant can be precisely controlled for preventing the leakage of the sealant. Furthermore, the channel is formed inside the coating layers on the TFT array substrate, so as to allow the sealant on the TFT array substrate have a constant height, thereby preventing an uneven thickness of the LC cell. Moreover, the sealant is coated in the channel for efficiently isolating the contact of the sealant and the LC molecules, preventing the contamination of the LC molecules, and improving the display effect of the LCD device.

The present invention has been described with a preferred embodiment thereof and it is understood that many changes and modifications to the described embodiment can be carried out without departing from the scope and the spirit of the invention that is intended to be limited only by the appended claims.

1-4. (canceled)

5. A method for manufacturing a liquid crystal display (LCD) device, characterized in that: the method comprises the following steps:
providing a first substrate, wherein the first substrate has a display region and a non-display region, and the non-display region is positioned around the display region;
forming coating layers on the display region and the non-display region;
patterning the coating layers on the display region and the non-display region, respectively, so as to form a switch array on the display region and form a stacked layer on the non-display region, wherein the stacked layer comprises at least one of the coating layers;
forming at least one channel on the stacked layer by exposure and developing;
filling the channel with a sealant; and
bonding the first substrate to a second substrate by using the sealant.

6. The method for manufacturing the LCD device according to claim 5, characterized in that: the sealant is higher than a top side of the channel by a bonding distance, and the stacked layer has a support height, and a total height of the support height and the bonding distance is equal to an inside distance between the first substrate and the second substrate after bonding them.

7. The method for manufacturing the LCD device according to claim 5, characterized in that: the coating layers comprise a gate insulating layer, an amorphous silicon layer and an ohmic contact layer, and the stacked layer comprises at least one of the gate insulating layer, the amorphous silicon layer and the ohmic contact layer.

8. The method for manufacturing the LCD device according to claim 5, characterized in that: when forming the channel on the stacked layer by exposure and developing, the channel and a pixel electrode on the display region are formed in the same mask process.

9. An LCD device, characterized in that: the LCD device comprises:
a first substrate comprising:
a switch array disposed on a display region of the first substrate;
a stacked layer formed on a non-display region of the first substrate, wherein the stacked layer comprises at least one coating layer; and
at least one channel formed on the stacked layer;
a sealant coated in the channel; and
a second substrate bonded to the first substrate by using the sealant.

10. The LCD device according to claim 9, characterized in that: the sealant is higher than a top side of the channel by a bonding distance, and the stacked layer has a support height, and a total height of the support height and the bonding distance is equal to an inside distance between the first substrate and the second substrate after bonding them.

11. The LCD device according to claim 9, characterized in that: the stacked layer comprises at least one of a gate insulating layer, an amorphous silicon layer and an ohmic contact layer.

12. An thin film transistor (TFT) array substrate, characterized in that:
the TFT array substrate comprises:
a substrate;
a switch array disposed on a display region of the substrate;
a stacked layer comprising at least one coating layer and formed on a non-display region of the substrate; and
at least one channel formed on the stacked layer configured to fill a sealant.

13. The TFT array substrate according to claim 12, characterized in that: the sealant is higher than a top side of the channel by a bonding distance, and the stacked layer has a support height, and a total height of the support height and the bonding distance is equal to an inside distance between a first substrate and a second substrate after bonding them.

14. The TFT array substrate according to claim 12, characterized in that: the stacked layer comprises at least one of a gate insulating layer, an amorphous silicon layer and an ohmic contact layer.
